(19) United States
(12) Patent Application Publication
(10) Pub. No.: US 2022/0209074 A1
(43) Pub. Date: Jun. 30, 2022

(54) LIGHT-EMITTING FILM, LIGHT-EMITTING FILM ARRAY, MICRO LIGHT EMITTING DIODE ARRAY, AND MANUFACTURING METHOD THEREOF

(71) Applicant: National Taiwan University, Taipei (TW)

(72) Inventors: Ching-Fuh Lin, Taipei (TW); Jung-Kuan Huang, Taipei (TW); Teng-Yi Huang, Taipei (TW); Yi-Shan Lin, Taipei (TW); Han-Yu Tsai, Taipei (TW)

(21) Appl. No.: 17/217,661

(22) Filed: Mar. 30, 2021

(30) Foreign Application Priority Data
Dec. 29, 2020 (TW) 109146589

(51) Int. Cl. H01L 33/50; H01L 25/075; H01L 33/56; H01L 33/58; H01L 33/60

(52) U.S. Cl. CPC H01L 33/502; H01L 25/0753; H01L 33/56; H01L 33/58; H01L 2933/0058; H01L 2933/0091; H01L 2933/0041; H01L 2933/005; H01L 33/60

(57) ABSTRACT

Embodiments of the present invention provide a light-emitting film, a light-emitting film array, a micro-light emitting diode (LED) array, and their manufacturing methods. In one embodiment, epitaxial layers are formed on a substrate, and a conversion film is formed on a corresponding epitaxial layer. Pixels can be defined through lithography with a very small pixel size. A mass transfer is unnecessary for this method. The produced light-emitting films and the conversion films are homogeneous films and are insoluble in water, and the manufacturing steps can be simplified due to the waterproofing function of the films.

### CROSS-REFERENCE TO RELATED APPLICATIONS

The entire contents of Taiwan Patent Application No. 109146589, filed on Dec. 29, 2020, from which this application claims priority, are expressly incorporated herein by reference.

### BACKGROUND OF THE INVENTION

### 1. Field of the Invention

The present invention relates to a light-emitting film, a light-emitting film array, a micro-light emitting diode (LED) array, and their manufacturing methods.

### 2. Description of Related Art

Micro light-emitting diode (microLED), also known as “mLED” or “μLED,” is an emerging flat-panel display technology. A micro light-emitting diode display is composed of an array of micro light-emitting diodes forming individual pixels. Compared to widely used liquid crystal display (LCD), micro light-emitting diode displays provide higher contrast, faster response time, and better energy efficiency.

Organic light-emitting diodes (OLEDs) and micro light-emitting diodes can greatly reduce energy consumption compared to conventional LCD systems. Unlike OLEDs, microlight-emitting diodes are based on conventional gallium nitride (GaN) light-emitting diode technology, which provides much higher total brightness, up to 30 times, and higher efficiency (lux/W) than OLEDs.

Generally, the dimension of a LED die is between 200 and 300 micrometers (μm), the dimension of a mini light-emitting diode die is about between 75 and 300 micrometers, and the dimension of a micro-light emitting diode die is smaller than about 75 microns.

During the manufacture of a micro light-emitting diode display, an epitaxial layer having a thickness of about 4-5 μm must be lifted off by a physical or chemical manner and then transferred onto a circuit substrate. Currently, the most significant challenge of manufacturing μLED is finding ways to place a huge amount of micron-level epitaxial layers on a target substrate or circuit through an apparatus with high precision, and this is known as “mass transfer.”

Taking a 4K television as an example, the number of epitaxial dies that need to be transferred is as high as 24 million. Even if it can be transferred 10,000 dies per time, it needs to be repeated 2,400 times. The yield and efficiency of massive transfers are highly technically difficult, so the field is actively researching breakthroughs.

### SUMMARY OF THE INVENTION

The present invention relates to a light-emitting film, a light-emitting film array, a micro-light emitting diode (LED) array, and their manufacturing methods.

According to an aspect of this invention, a light-emitting film is provided with one or more light-emitting materials and a polymer. Each light-emitting material is capable of re-radiating photons or electromagnetic radiation after the absorption of photons or electromagnetic radiation. The polymer eliminates grain boundaries and scattering of the one or more light-emitting materials. The produced light-emitting film is a homogeneous film without grain boundaries of the one or more light-emitting materials and is insoluble in water.

According to another aspect of this invention, a micro light-emitting diode array is provided with a substrate, epitaxial layers, first conversion films, and second conversion films. The epitaxial layers are formed on the substrate to emit a light of a first color. The epitaxial layers comprise first upper surfaces and second upper surfaces. One first conversion film is formed on each first upper surface of the epitaxial layers. One second conversion film is formed on each second upper surface of the epitaxial layers. Each of the first conversion film and the second conversion film comprises one or more light-emitting materials and a polymer. Each light-emitting material is capable of re-radiating photons or electromagnetic radiation after the absorption of photons or electromagnetic radiation. The polymer eliminates grain boundaries and scattering of the one or more light-emitting materials. Each of the first conversion film and the second conversion film is a homogeneous film without grain boundaries of the one or more light-emitting materials and is insoluble in water.

### BRIEF DESCRIPTION OF THE DRAWINGS

FIG. 1 is a schematic diagram showing a method for manufacturing a light-emitting film array in accordance with an embodiment of the present invention.

FIGS. 2A to 2F are schematic diagrams showing a method for manufacturing a micro light emitting diode array in accordance with an embodiment of the present invention.

FIG. 3A shows a micro light emitting diode array in accordance with another embodiment of the present invention.

FIG. 3B shows a micro light emitting diode array in accordance with another embodiment of the present invention.

FIG. 3C shows a micro light emitting diode array in accordance with another embodiment of the present invention.

FIG. 3D shows a micro light emitting diode array in accordance with another embodiment of the present invention.

FIGS. 4A to 4D show the transmittance, reflection, and absorption spectra of light-emitting films in accordance with an embodiment of the present invention wherein the films have different film thicknesses and concentrations of the organic light-emitting material.

FIG. 5 shows the transmittance, reflection, and absorption spectra of a pure PVB film in accordance to an embodiment of the present invention.

FIGS. 6A to 6C respectively show the excitation and emission spectra of the light-emitting solutions having different concentration of the organic light-emitting material in accordance with an embodiment of the present invention.

FIGS. 7A and 7B are cross-sectional and top scanning electron microscope photos of a light-emitting film/conversion film in accordance with an embodiment of the present invention.

### DETAILED DESCRIPTION OF THE PREFERRED EMBODIMENT

Reference will now be made in detail to those specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations and components are not described in detail in order not to unnecessarily obscure the present invention.

According to some embodiments of this invention, a light-emitting thin film is provided with one or more light-emitting materials and a polymer. The light-emitting thin film is preferably made of a solution process. The one or more light-emitting materials and the polymer are firstly dissolved in a solvent to form a light-emitting solution, which is then formed on a substrate. After that, the solvent is removed from the light-emitting solution to form a light-emitting thin film on the substrate. After the light-emitting thin film is formed, the polymer keeps the properties of the one or more light-emitting materials, e.g., the polarity and absorption and radiation wavelength range, as in the liquid form. And/or, the polymer eliminates grain boundaries and scattering of the one or more light-emitting materials. The light-emitting film made by the above-mentioned method has a good film-forming and cladding properties, and is a homogeneous film without grain boundaries of the one or more light-emitting materials. Preferably, the produced light-emitting film is insoluble in water.

In the present disclosure, the light-emitting materials are photoluminescent materials which re-radiate photons (electromagnetic radiation) after the absorption of photons (electromagnetic radiation). According to embodiments of this invention, the light-emitting materials can be organic or inorganic light-emitting materials.

In one embodiment, the light-emitting materials are inorganic light-emitting materials, such as zinc oxide (ZnO).

In some embodiments, the light-emitting materials are organic dyes comprising non-rare earth elements. In addition, the polymer keeps the polarity of the organic dyes and hence keeps absorption and radiation wavelength range as it in the liquid form.

In some embodiments, the polymer is an organic dye that may include but is not limited to, DILATED CARDIOMYOPATHY 2 (DCM2), DCJTB, DCQTB, C545, etc. The full name of DCM2 is 2{4-dicyanomethylene-2-methyl-6-[2-(2,3,6,7-tetrahydro1H,5H-benzo[i,j]quinolizin-8-yl)vinyl]-4H-pyran}. The full name of C545T is 10-(2-Benzothiazolyl)-2,3,6,7-tetrahydro-1,1,7,7-tetramethyl-1H,5H,11H-(1) benzopyropyrano(6,7-8-I,j) quinolizin-11-one. The full name of DCJTB is 2-tert-Butyl-4-(dicyanomethylene)-6-[2-(1,1,7,7-tetramethyljulolidin-9-yl)vinyl]-4H-pyran. The full name of DCQTB is (E)-2-(2-tert-Butyl-6-(2-(2,6,6-trimethyl-2,4,5,6-tetrahydro-1H-pyrrolo[3,2,1-ij]quinolin 8-yl)vinyl)-4H-pyran-4-ylidene)malononitrile.

In some embodiments, the solvent may include but is not limited to: methanol, ethanol, chloroform, tetrahydrofuran, dichloromethane, and/or other solvents that can dissolve the one or more organic dyes and the polymer.

In some embodiments, the polymer may include but is not limited to: poly(vinyl butyral) (PVB), polyvinyl alcohol, polyvinylidene chloride, ethylene-vinyl acetate copolymer, poly(vinyl butyral), vinylpyrrolidone, polyvinyl acetal, polyvinyl butyral, methacrylate-methacrylic acid copolymer, polyvinyl chloride, polydimethylsiloxane, polyvinylcarbazole, polystyrene, or polyphenylene oxide.

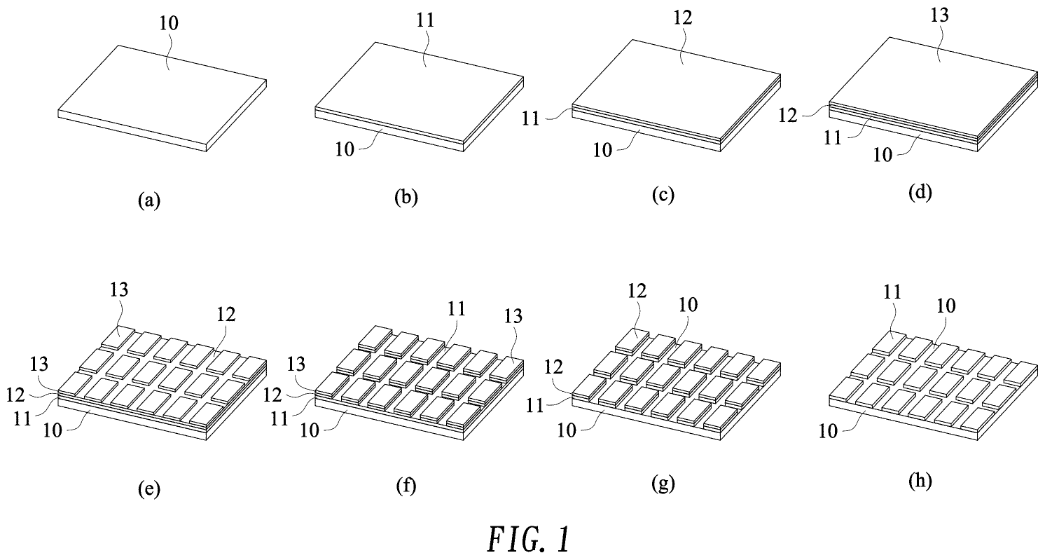

Some embodiments of the present invention provide a light-emitting film array. FIG. 1 illustrates a method for manufacturing a light-emitting film array according to an embodiment of the present invention.

First, add an appropriate amount of a solvent into a bottle containing a magnetic stirring bar, where the solvent is selected from one or more of ethanol, methanol, and tetrahydrofuran. In this example, tetrahydrofuran is used as the solvent.

Next, add about 1 to 10 mg of one or more fluorescent dyes into the bottle and dissolve them with the solvent. The one or more fluorescent dyes are selected from DCM2, DCJTB, and DCQTB. In this example, DCM2 is used as the organic dye.

Next, add 1 to 2 g of PVB into the above bottle. Then place the bottle on a hotplate and stir for 30 to 40 minutes to completely dissolve the fluorescent dye and PVB in the solvent so as to form a light-emitting solution.

Referring to step (a) of FIG. 1, the substrate 10 (for example, a glass substrate) is washed by a washing machine using acetone, IPA, and deionized water for 5 minutes, respectively, and then is placed in an oven to dry.

Referring to step (b) of FIG. 1, then, place the cleaned substrate 10 on a base of a spin coater and hold it by vacuum, and use a dropper to take the light-emitting solution from the bottle and evenly apply it to the surface of the glass substrate 10. Next, set parameters of the spin coater, spin coating with an initial rotational speed of 2500 rpm for 10 seconds, and then spin coating with a final rotational speed of 6000 rpm for 40 seconds, so as to form a light-emitting film 11 on the substrate 10. After the spin coating is completed, stop the vacuum pump and remove the substrate 10. Next, the substrate 10 with the light-emitting film 11 is placed on a hotplate and heated at 100° C. for 30 min, and then the substrate 10 is removed from the hotplate.

Referring to step (c) of FIG. 1, then, the substrate 10 is placed in an electron beam evaporator, and a protective layer 12, e.g., a SiO₂ layer with thickness of 200 nm, is deposited on the light-emitting film 11 with an electron gun (E-gun), where the evaporation pressure is 5×10⁻⁶ torr, and the plating rate depends on the growth thickness of the protective layer 12 as follows: 0.1 A (1˜5 nm); 0.5 A (5-20 nm); 1.0 A (20-100 nm); 1.5 A (100-180 nm); 0.5 A (180-200 nm).

Referring to step (d) of FIG. 1, then, the substrate 10 coated with the protective layer 12 is coated with a photoresist 13, e.g., S1813 positive photoresist, by the spin coater using an initial rotational speed of 1000 rpm for 10 seconds and a final rotational speed of 4000 rpm for 40 seconds, and is then placed on the hotplate to be heated for 3 minutes to evaporate the solvent.

Referring to step (e) of FIG. 1, then, the sample coated with the photoresist 13 is exposed and developed to pattern the photoresist 13. The exposure time is 20 seconds, and the development time is varies, about 8 to 20 seconds, depending on the size of the light-emitting film array.

Referring to step (f) of FIG. 1, after the exposure and development, the substrate 10 is placed in a reactive ion etching (RIE) system for etching. First, the SiO₂ protective layer 12 is etched away. The parameters for RIE are listed as follows: gas and flow rate: CHF₃ (30 sccm); chamber pressure: 1.3 pa; RF power: 100 W; etching time: 30 mins.

Referring to step (g) of FIG. 1, the RIE etching is continued to remove the patterned photoresist layer 13 and a portion of the light-emitting layer 11 that is not shielded by the patterned photoresist layer 13, where the parameters for etching are as follows: gas and flow rate: O₂ (50 sccm); chamber pressure: 13.3 Pa; RF power: 100 W; etching time: 30 mins. A red light-emitting film array is then completed. In particular, the produced red light-emitting film array is insoluble in water.

Referring to step (h) of FIG. 1, the etching process can be continued to remove the protective layer 12 on the light-emitting films 11. Alternatively, this step can be omitted and the protective layer 12 can remain on the light-emitting film 11.

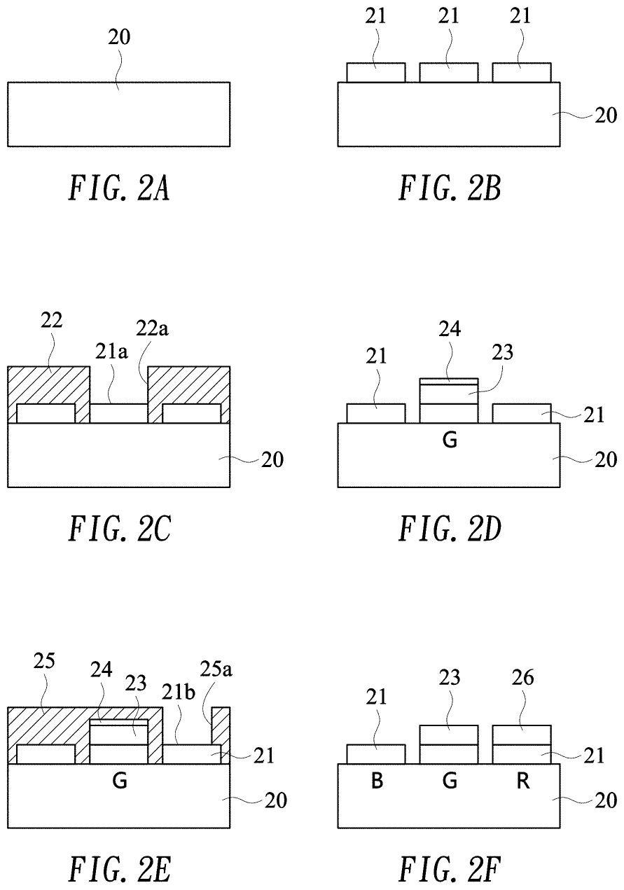

FIGS. 2A to 2F are schematic views showing a method of fabricating a micro light emitting diode array in accordance with an embodiment of the present invention.

Referring to FIG. 2A, a substrate 20 is provided. The substrate 20 may include, but is not limited to, a sapphire substrate, a glass substrate, a silicon substrate, a silicon carbide substrate, a plastic substrate, or other semiconductor substrates. The substrate 20 is cleaned using normal procedures well known in the art.

Referring to FIG. 2B, a plurality of epitaxial layers 21 are formed on the upper surface of the substrate 20 by employing an epitaxial process, e.g., a metal organic chemical vapor deposition (MOCVD) method. By using a mask (not shown), these epitaxial layers 21 can be formed on the substrate 2 at positions where the pixels will be formed. The epitaxial layers 21 can emit light of a first color.

Referring to FIG. 2C, a first mask 22 defining a plurality of openings 22a is formed or disposed on the epitaxial layer 21 to selectively expose the first upper surfaces 21a of the epitaxial layers 21. The first mask 22 may be a patterned photoresist layer, or may be composed of other materials such as silicon dioxide or the like. Taking a patterned photoresist layer as an example, it can be formed using a procedure known in the art such as photolithography or electron-beam lithography. For example, a photoresist layer is first coated on the epitaxial layers 21, and a pattern is transferred to the photoresist layer by performing an exposure with a suitable light source, thereby defining the openings 22a.

In one embodiment, a photoresist S1813 is coated on the epitaxial layer 21, followed by soft bake at 115° C. for 3 minutes. Next, the photoresist is exposed for 18 seconds. Next, the substrate 20 is immersed in the developer MF-319 for 12 seconds, and then immersed in deionized water for 3 to 5 seconds. Next, the substrate 10 is hard baked at 125° C. for 1 minute after it is dried. Next, the openings 22a are formed by reactive-ion etching with the RF power setting to 100 W and dry etching the photoresist using 02 gas.

Referring to FIG. 2D, a first conversion film 23 is formed on each first upper surface 21a of the epitaxial layers 21. If the first mask 22 is a photoresist, a protective layer 24 may be formed on the first conversion film 23 after the first conversion film 23 is formed. The protective layer 24 may be silicon oxide and may be deposited using an electron gun (E-gun) evaporation system. Next, the first mask 22 is removed or stripped using reactive ion etching.

Referring to FIG. 2E, a second mask 25 defining a plurality of openings 25a is formed or disposed on the epitaxial layers 21 to selectively expose the second upper surfaces 21b of the epitaxial layers 21. The second mask 25 may be a patterned photoresist layer, or may be composed of other materials such as silicon oxide or the like. Taking the patterned photoresist layer 25 as an example, it can be formed using a technique known in the art such as optical lithography or electron beam lithography. For example, a photoresist layer is first coated on the epitaxial layers 21, and a pattern is transferred to the photoresist layer by performing an exposure with a suitable light source, thereby defining the openings 25a.

In one embodiment, a photoresist S1813 is coated on the epitaxial layers 21, followed by soft bake at 115° C. for 3 minutes. Next, the photoresist is exposed for 18 seconds. Next, the substrate 20 is immersed in the developer MF-319 for 12 seconds, and then immersed in deionized water for 3 to 5 seconds. Next, the substrate 20 is hard baked at 125° C. for 1 minute after it is dried. Next, the openings 25a are formed by reactive-ion etching with the RF power setting to 100 W and dry etching the photoresist using 02 gas.

Referring to FIG. 2F, a second conversion film 26 is formed on each second upper surface 21b of the epitaxial layers 21. Next, the second mask 25 is removed or stripped using reactive ion etching.

The mentioned light-emitting film or light-emitting film array in the foregoing embodiments may be used as the conversion films, such as the first conversion film 23 and the second conversion film 26. Preferably, the conversion films are produced by a solution method. Both one or more light-emitting materials and a polymer are dissolved in a solvent to form a light-emitting solution, which is then formed on the needed positions, such as the first upper surface 21a or the second upper surface 21b. After that, a first conversion film 23 is formed on the first upper surface 21a by removing (e.g., drying) the solvent from the light-emitting solution. Or, a second conversion film 26 is formed on the second upper surface 21b by removing (e.g., drying) the solvent from the light-emitting solution. Preferably, the one or more light-emitting materials are organic photoluminescent materials that absorb a light with a first color and re-radiate a light with a second color. Preferably, the one or more light-emitting materials are non-rare earth elements.

In some embodiments, the weight ratio of the organic dyes to the polymer ranges between 1:200 and 1:20000. In one embodiment, method for forming the light-emitting solution on a needed position (such as the first upper surface 21a and the second upper surface 21b) may comprise, but is not limited to, spin coating, dip coating, ink jet printing, screen printing, comma coating, or roll coating. In one embodiment, the light-emitting solution is formed on a needed position by spin coating and the coating time is between 10 sec and 3 min. Next, the solvent is removed from the light-emitting solution so as to form a conversion film, e.g., the first conversion film 23 or the second conversion film 26. In one embodiment, the solvent can be removed from the light-emitting solution by natural (air) seasoning or other manners. The first conversion film 23 or the second conversion film 26 is formed once the solvent is removed.

In the embodiment shown in FIGS. 2A-2F, the epitaxial layers 21 can emit a blue light, and the first conversion films 23 absorb the blue light emitted from the epitaxial layers 21 and then emit a green light. In addition, the second conversion films 26 absorb the blue light emitted from the epitaxial layers 21 and then emit a red light. Embodiments of the invention are not limited thereto and may have other arrangements.

An embodiment of preparing the first conversion film 23 is exemplified below.

Firstly, an organic dye, C545T, is dissolved with a proper solvent, e.g., ethanol. In other embodiments, the solvent ethanol can be replaced by another solvent capable of dissolving the organic dye C545T.

After that, the solution of C545T and solvent is agitated for 30 min so that C545T is completely dissolved and a light-emitting solution capable of emitting green light is formed. A polymer, such as polyvinyl butyral (PVB), is then added into the above light-emitting solution.

After that, a heating plate is preheated to 60° C. and then used to heat the light-emitting solution. During the heating, the light-emitting solution is agitated until the polyvinyl butyral (PVB) is completely dissolved.

The light-emitting solution capable of emitting green light is then spin-coated on the target positions (e.g., the first upper surfaces 21a) with a speed between 500 rpm and 9000 rpm for 10 sec.

After that, the substrate 20 is placed under atmosphere, so as to evaporate the solvent from the light-emitting solution and thus gradually form a first conversion film 23 capable of emitting green light. Finally, a protective layer 24 may be deposited on the first conversion film 23.

The method of manufacturing the second conversion films 26 may refer to the mentioned method to produce the light-emitting film array.

Although the conversion films of the above-mentioned embodiment emits a single color light within a wavelength band, in other embodiments two or more organic dyes may be used so that the produced conversion film can emit two or more color lights with one or more wavelength bands.

A person skilled in the art can make various modifications, substitutions, or alterations to the embodiments shown in FIGS. 2A-2F, and such modifications, substitutions, or alterations are within the scope of the invention.

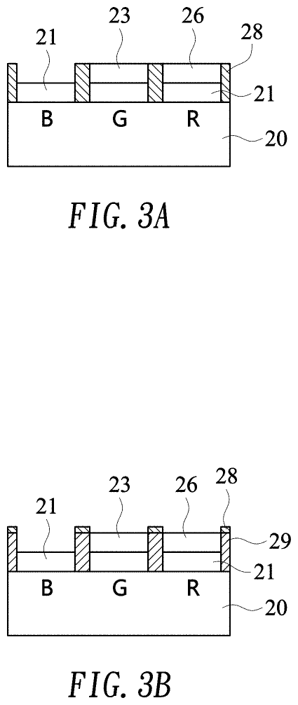

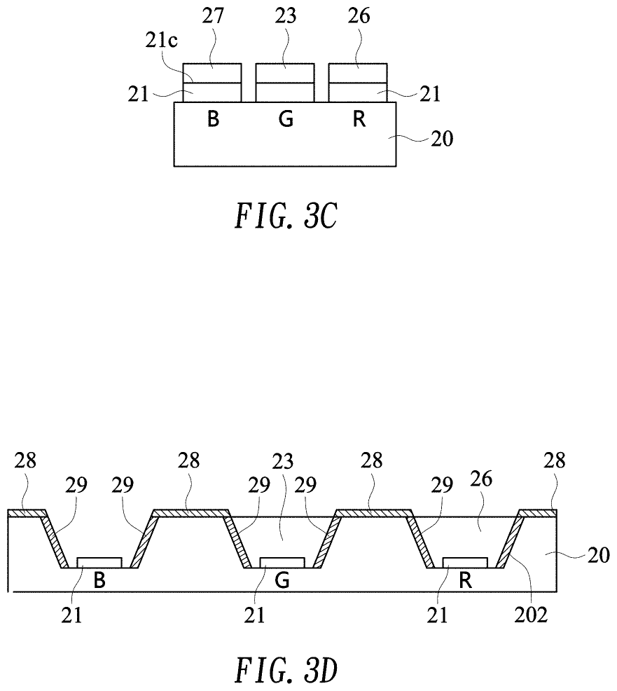

FIG. 3A shows a micro light emitting diode array according to another embodiment of the present invention. In this embodiment, the method as shown in FIGS. 2A to 2F further includes a step of forming a black matrix 28 around respective epitaxial layers 21 and the conversion films 23/26. The black matrix 28 may be made of a metal, such as chromium.

In one embodiment, after the light-emitting diode array of FIG. 2F is completed, a black matrix 28 is fabricated as follows. First, a spin coater is used to coat a photoresist NR9 on the light-emitting diode array of FIG. 2F. The light-emitting diode array coated with NR9 is then soft-baked at 130° C. for 1 minute and then exposed for 10 seconds. The light-emitting diode array is then post-exposure baked at 115° C. for 1 minute, and then developed for about 4 sec by a developer RD6, so as to produce a patterned photoresist layer for forming the black matrix 28. Next, by using the patterned photoresist layer and the electron gun (E-gun) with the evaporation rate: 0.1 A (1˜5 nm); 0.5 A (5-20 nm); 1.0 A (20˜45 nm), a chromium layer with thickness of 45 nm is deposited. Finally, acetone is used to strip off the photoresist layer above the epitaxial layers 21, and a portion of the chromium layer deposited on the photoresist layer is also stripped off together with the photoresist layer. The remaining chromium layer forms the black matrix 28.

FIG. 3B shows a micro light emitting diode array according to another embodiment of the present invention. In this embodiment, the method as shown in FIGS. 2A to 2F further includes a step of forming a reflective layer 29 around respective epitaxial layers 21 and the conversion films 23/26 and forming a black matrix 28 on the reflective layer 29. The reflective layer 29 may be made of a metal, such as silver. Preferably, after the first conversion film 23 is formed, a reflective layer 29 can be formed at the periphery of the first conversion film 23. After the second conversion film 24 is formed, a reflective layer 29 is formed at the periphery of the second conversion film 24. And a reflective layer 29 may be formed at the periphery of the epitaxial layer 21 of the blue pixel before or after the first conversion film 23 is formed. The reflective layers 29 can be deposited using an electron gun (E-gun). For example, after the first conversion film 23 is formed, a patterned photoresist layer (for example, a patterned S1813 positive photoresist layer) is made by exposure and development, and then silver is deposited around the first conversion film 23 by oblique evaporation to form the reflective layer 29. Then the black matrix 28 can be deposited on the reflective layer 29. In some embodiments, the reflective layer 29 is a metal reflective layer, and it may be made of aluminum, aluminum alloy, gold, silver, copper, platinum, titanium, or a combination of the foregoing materials. In some embodiments, the reflective layer 29 is a multi-layered distributed Bragg reflector, which may be made of SiO₂/TiO₂ (titanium dioxide), SiO₂/Si₃N₄ (silicon nitride), SiO₂/HfO₂ (hafnium dioxide), SiO₂/ZrO₂ (zirconium dioxide), and/or SiO₂/Y₂O₃ (yttria).

FIG. 3C shows a micro light emitting diode array according to another embodiment of the present invention. In this embodiment, the epitaxial layers 21 emit an ultraviolet light, and a plurality of third conversion films 27 are formed on a plurality of third upper surfaces 21c of the epitaxial layers 21. After absorbing the ultraviolet light, the first, second, and third conversion films respectively emit another color of light, such as a green light, a red light, and a blue light. In another embodiment, a plurality of fourth conversion films (not shown) are further formed on a plurality of fourth upper surfaces (not shown) of the epitaxial layers 21. In one embodiment, the epitaxial layers 21 and/or at least one kind of the conversion films may be integrally formed on the substantially whole surface of the substrate 20, and then the integrally formed epitaxial layers 21 and/or the conversion film is patterned by lithography to define pixels. In this embodiment, the periphery of each epitaxial layer 21 and conversion film 23/26/27 may also include the aforementioned black matrix 28 or the reflective layer 29 and the black matrix 28.

FIG. 3D shows a micro light emitting diode array according to another embodiment of the present invention. The difference between this embodiment and the embodiment of FIGS. 2A to 2F is that the substrate 20 has a plurality of grooves 202. The grooves 202 may be rectangular or trapezoidal as shown in FIG. 3D, wherein the length of the upper base may be greater than the length of the lower base of the trapezoid. An epitaxial layer 21 is formed in respective grooves 202. For example, the epitaxial layer 21 is formed on the bottom of the trapezoidal groove 202. In addition, a reflective layer 29 may be formed, e.g., by evaporation, on the side surface of the groove 202. In another embodiment, the periphery of the epitaxial layer 21 at the bottom of the trapezoidal groove 202 is also plated with a reflective layer 29. After the epitaxial layer 21 is formed in respective grooves 202, the first conversion film 23 and the second conversion film 26 are sequentially formed in the corresponding groove 202. Different from the foregoing embodiments, the light-emitting solution can be ink-jetted or dripped into the groove, and then dried to form the first conversion film 23 or the second conversion film 26. In addition, the black matrix 28 may be formed around the groove 202 before or after the first conversion film 23 and the second conversion film 26 are formed.

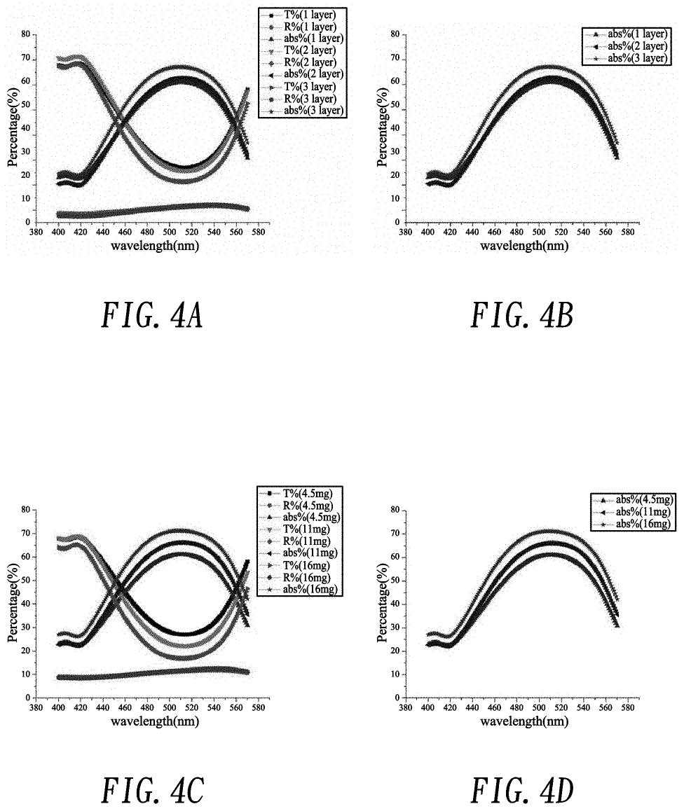

FIGS. 4A to 4B show the transmittance (T %), reflection (R %), and absorption (abs %) spectra of three red light-emitting films according to embodiments of the present invention wherein the films have different film thicknesses. The five films are spin-coated with one to three layers of red light-emitting solutions, and the thickness of one spin-coated layer is about 10 nm after the light-emitting solution is dried. In addition, the weight of the phosphors in each film is fixed at 4.5 mg. It can be observed from FIGS. 4A-4B that the reflection is hardly affected by changes in the thickness of the light-emitting film.

FIGS. 4C and 4D show the transmittance (T %), reflection (R %), and absorption (abs %) spectra of three red light-emitting films according to embodiments of the present invention wherein the films have different concentrations of the organic light-emitting material. The weights of the phosphors in the three films are 4.5 mg, 11 mg, and 16 mg, respectively.

Table 1 lists the absorptions of the light-emitting films of FIGS. 4A-4D. As shown in table 1 and FIGS. 4A to 4D, the absorptions of the red light films are greater than 50% between 460 nm and 530 nm.

TABLE 1

| | Light-emitting film | | | | |
|---|---|---|---|---|---|
| | 4.5 mg | 4.5 mg | 4.5 mg | 11 mg | 16 mg |
| abs. % | 1-layer | 2-layer | 3-layer | 1-layer | 1-layer |
| 460 nm abs.(%) | 45.47% | 45.95% | 52.02% | 49.59% | 56.14% |
| 530 nm abs.(%) | 58.94% | 60.66% | 65.04% | 64.19% | 69.32% |

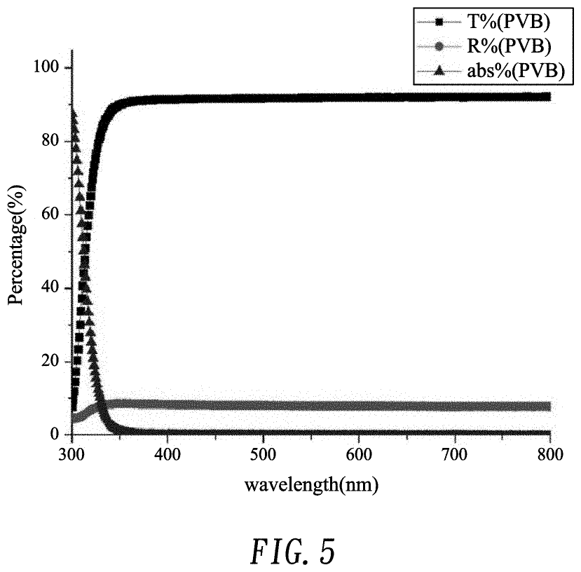

FIG. 5 shows the transmittance, reflection, and absorption spectra of a pure PVB film in accordance to an embodiment of the present invention. As shown in FIG. 5, the transmittance of the PVB film is above 90% in the wavelength range between 350 nm and 800 nm. Therefore, when PVB is used as the polymer to produce the light-emitting films, PVB will not affect the absorption of the light (such as blue light) by the light-emitting material.

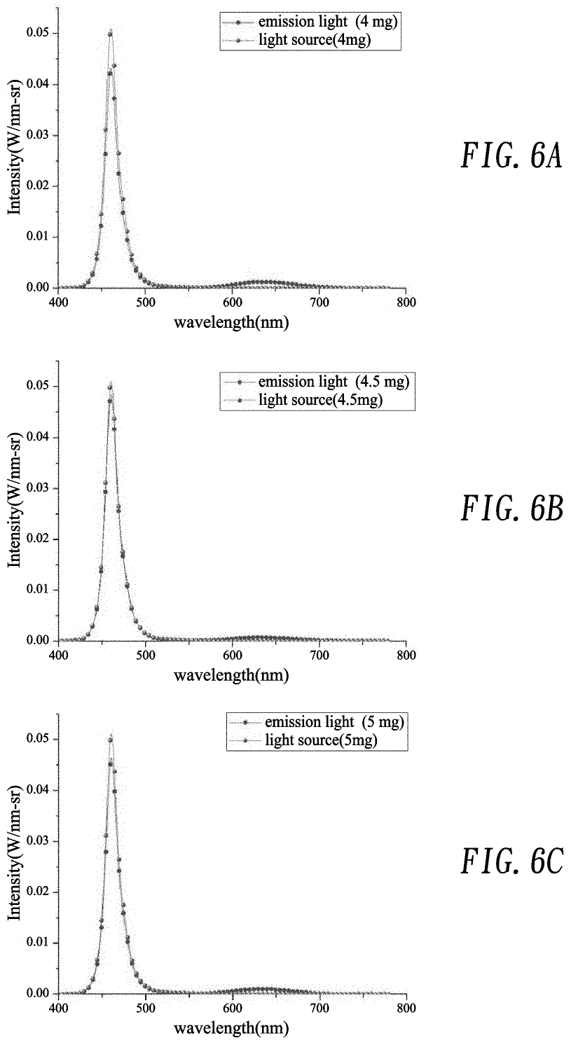

FIGS. 6A to 6C respectively show the excitation and emission spectra of the red light-emitting solutions having different concentration (4 mg, 4.5 mg, and 5 mg) of the organic light-emitting material in accordance with an embodiment of the present invention. A blue light with wavelength of 460 nm is used as the light source (excitation light) to irradiate the light-emitting solution. The irradiating time is 100 ms, and the quantum efficiencies (QE) of the samples in FIGS. 6A to 6C are 81.9%, 90.0%, and 83.2%, respectively.

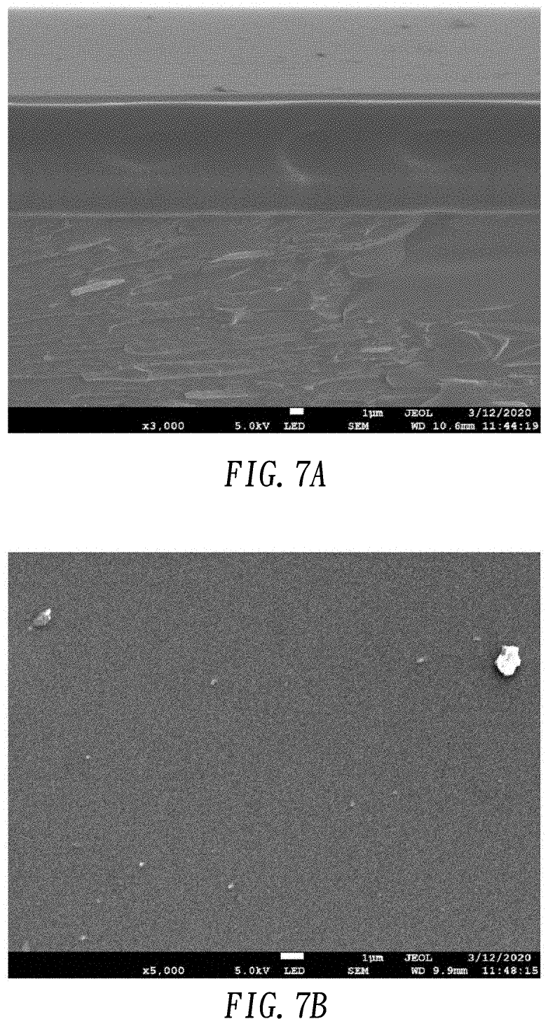

FIGS. 7A and 7B are cross-sectional and top scanning electron microscope photos of a light-emitting film/conversion film manufactured according to an embodiment of the present invention. As shown in FIGS. 7A and 7B, the light-emitting film/conversion film produced by the present invention does not have the grain boundaries of the light-emitting materials. By contrast, a film formed by conventional fluorescent materials includes grain boundaries. During the manufacture of a conventional light emitting diode display, because the formed film includes grain boundaries, the size of pixel cannot be too small. For example, if the average grain size of the fluorescent particles is 10 μm, in order to make the brightness of the individual pixels uniform, it is necessary to increase the number of fluorescent particles per pixel, for example, 100 fluorescent particles per pixel. This will result in a large size of unit pixel, usually greater than 100 μm.

In contrast, each conversion film produced by the present invention is a continuous or homogeneous film because it does not have grain boundaries of the phosphors. Therefore, the size of unit pixel (i.e., the size of the epitaxial layer) is not limited to the average brightness and can be arbitrarily defined. In some embodiments, the size of one pixel is equal to or less than 75 μm. In some embodiments, the size of one pixel is equal to or less than 15 μm. In some embodiments, the size of one pixel is equal to or less than 10 μm. In some embodiments, the size of one pixel ranges from 1 μm to 10 μm. In some embodiments, the size of one pixel is equal to or less than 5 μm.

In addition, because each conversion film of the present invention is a continuous/homogeneous film without grain boundaries of the phosphors, it is possible to define pixels by patterning the conversion film with a conventional lithography. Alternatively, the conversion film of the present invention may be directly formed on the first upper surface, the second upper surface, and/or the third upper surface of the epitaxial layers. In this way, the method provided by the present invention does not require massive transfer of the epitaxial layers and thus greatly improve the yield and save a lot of time.

In addition, the light-emitting film, the light-emitting film array, and the conversion film prepared by embodiments of the present invention are insoluble in water, which provides a moisture resistance effect during the manufacturing process, and therefore protection steps and/or mechanism from the moisture required in the manufacturing process can be omitted, and the applicability and reliability of the final product are increased.

Although specific embodiments have been illustrated and described, it will be appreciated by those skilled in the art that various modifications may be made without departing from the scope of the present invention, which is intended to be limited solely by the appended claims.

What is claimed is:

1. A light-emitting film, comprising:
one or more light-emitting materials, with each being capable of re-radiating photons or electromagnetic radiation after the absorption of photons or electromagnetic radiation; and
a polymer for eliminating grain boundaries of the one or more light-emitting materials and scattering of the one or more light-emitting materials;
wherein the light-emitting film is a homogeneous film without grain boundaries of the one or more light-emitting materials and is insoluble in water.

2. The light-emitting film as recited in claim 1, wherein the absorption of the light-emitting film is equal to or more than 50% between wavelength 460 nm and 530 nm.

3. The light-emitting film as recited in claim 1, wherein the polymer comprises polyvinyl butyral (PVB), polyvinyl alcohol, polyvinylidene chloride, ethylene-vinyl acetate copolymer, poly(vinyl butyral), vinylpyrrolidone, polyvinyl acetal, polyvinyl butyral, methacrylate-methacrylic acid copolymer, polyvinyl chloride, polydimethylsiloxane, polyvinylcarbazole, polystyrene, or polyphenylene oxide.

4. The light-emitting film as recited in claim 1, wherein the one or more light-emitting materials comprise one or more organic dyes.

5. A micro light-emitting diode array, comprising:
a substrate;
a plurality of epitaxial layers on the substrate to emit a light of a first color;
a first conversion film formed on each of a plurality of first upper surfaces of the epitaxial layers; and
a second conversion film formed on each of a plurality of second upper surfaces of the epitaxial layers;
wherein, each of the first conversion film and the second conversion film comprises:
one or more light-emitting materials, with each being capable of re-radiating photons or electromagnetic radiation after the absorption of photons or electromagnetic radiation; and
a polymer for eliminating grain boundaries of the one or more light-emitting materials and scattering of the one or more light-emitting materials;
wherein each of the first conversion film and the second conversion film is a homogeneous film without grain boundaries of the one or more light-emitting materials and is insoluble in water.

6. The micro light-emitting diode array as recited in claim 5, wherein each epitaxial layer defines a pixel, and the size of the pixel is less than or equal to 75 μm.

7. The micro light-emitting diode array as recited in claim 5, further comprising a third conversion film formed on each of a plurality of third upper surfaces of the epitaxial layers.

8. The micro light-emitting diode array as recited in claim 5, further comprising a black matrix at the periphery of respective epitaxial layers, the first conversion films, and the second conversion films.

9. The micro light-emitting diode array as recited in claim 5, further comprising:
a reflective layer at the periphery of respective epitaxial layers, the first conversion films, and the second conversion films; and
a black matrix on the reflective layer.

10. The micro light-emitting diode array as recited in claim 5, wherein the substrate comprises a plurality of grooves, and the epitaxial layers, the first conversion films, and the second conversion films are formed in the corresponding grooves.

11. The micro light-emitting diode array as recited in claim 10, wherein the grooves are rectangular.

12. The micro light-emitting diode array as recited in claim 10, wherein the grooves are trapezoidal, the length of the lower base of the trapezoid is less than the length of the upper base of the trapezoid, and the epitaxial layers are located on the lower bases of the trapezoidal grooves.

13. The micro light-emitting diode array as recited in claim 10, wherein side walls of each of the grooves further comprise a reflective layer.

14. The micro light-emitting diode array as recited in claim 10, wherein the reflective layer is a metal reflective layer and is made of aluminum, aluminum alloy, gold, silver, copper, platinum, titanium, or a combination thereof.

15. The micro light-emitting diode array as recited in claim 10, wherein the reflective layer is a distributed Bragg reflector and is made of SiO₂/TiO₂ (titanium dioxide), SiO₂/Si₃N₄ (silicon nitride), SiO₂/HfO₂ (hafnium dioxide), SiO₂/ZrO₂ (zirconium dioxide), and/or SiO₂/Y₂O₃ (yttria).

16. The micro light-emitting diode array as recited in claim 10, further comprising a black matrix around respective grooves.

17. The micro light-emitting diode array as recited in claim 5, wherein the one or more light-emitting materials comprise organic dyes and are non-rare earth elements, and the polymer keeps the polarity and absorption and radiation wavelength range of the organic dyes as in the liquid form.

18. The micro light-emitting diode array as recited in claim 17, wherein the organic dyes comprise C545T, DCJTB, DCM2, or DCQTB.

19. The micro light-emitting diode array as recited in claim 5, wherein the polymer comprises polyvinyl butyral (PVB), polyvinyl alcohol, polyvinylidene chloride, ethylene-vinyl acetate copolymer, poly(vinyl butyral), vinylpyrrolidone, polyvinyl acetal, polyvinyl butyral, methacrylate-methacrylic acid copolymer, polyvinyl chloride, polydimethylsiloxane, polyvinylcarbazole, polystyrene, or polyphenylene oxide.
